(19) United States
(12) Patent Application Publication
(10) Pub. No.: US 2026/0163455 A1
(43) Pub. Date: Jun. 11, 2026

(54) ELECTRIC WORK MACHINE

(71) Applicant: MAKITA CORPORATION, Anjo-shi (JP)

(72) Inventors: Kisho SEKIDO, Anjo-shi (JP); Shunta MIZUNO, Anjo-shi (JP); Shintaro AKIYAMA, Anjo-shi (JP); Ryosuke SUZUKI, Anjo-shi (JP)

(73) Assignee: MAKITA CORPORATION, Anjo-shi (JP)

(21) Appl. No.: 19/407,832

(22) Filed: Dec. 3, 2025

(30) Foreign Application Priority Data
Dec. 6, 2024 (JP) 2024-213812

(51) Int. Cl. H02K 11/33; B27B 17/08; H05K 1/11

(52) U.S. Cl. CPC H02K 11/33; H05K 1/115; H05K 1/181; B27B 17/08; H05K 2201/10166

(57) ABSTRACT

An electric work machine including a motor, a circuit board, a first semiconductor switch, a second semiconductor switch, a first conductive trace, a second conductive trace, and a solid metal component. The circuit board includes a first circuit surface, a second circuit surface, and a through-hole. The first semiconductor switch is mounted on the first circuit surface and includes a first terminal. The second semiconductor switch is mounted on the second circuit surface and includes a second terminal. The first conductive trace is arranged on the first circuit surface and is electrically coupled to the first terminal. The second conductive trace is arranged on the second circuit surface and is electrically coupled to the second terminal. The solid metal component is inserted into the through-hole and is electrically coupled to the first conductive trace and to the second conductive trace.

### CROSS-REFERENCE TO RELATED APPLICATIONS

This application claims the benefit of Japanese Patent Application No. 2024-213812 filed on Dec. 6, 2024 with the Japan Patent Office, the entire disclosure of which is incorporated herein by reference.

### BACKGROUND

The present disclosure relates to an electric work machine including semiconductor switches.

A power tool disclosed in Japanese U.S. Pat. No. 5,512,110 includes a tool bit, a motor that generates a driving force for driving the tool bit, and a drive circuit for driving the motor. The drive circuit includes six switching devices. Three of the six switching devices are mounted on the front surface of a power circuit board of the power tool, and the other three are mounted on the rear surface of the power circuit board.

### SUMMARY

In the above-described power tool, in order to allow an electric current to flow from the switching device on the front surface to the switching device on the rear surface, the power circuit board may be provided with: a via passing through the power circuit board; and a printed wiring coupling the via to the switching devices. The width of this printed wiring corresponds to the via diameter and is relatively narrow. Thus, the inductance of the printed wiring is relatively high. This results in relatively large surge voltages generated on the current path in association with the switching operations of the switching devices. Accordingly, it is necessary to increase the rated voltage of each switching device. In general, as the rated voltage of the switching device is increased, the on-resistance value of the switching device is also increased. Such an increase in the on-resistance value results in an increase in the heat generation in association with conduction of the switching device.

It is desirable that one aspect of the present disclosure be capable of reducing the inductance of a current path on a circuit board of an electric work machine.

In the present disclosure, ordinal numbers such as “first” and “second” are merely intended to distinguish the elements from each other, and are not intended to limit the order and/or number of the elements. Thus, the first element may be referred to as the second element, and similarly, the second element may be referred to as the first element. In addition, the first element may be provided without the second element, and similarly, the second element may be provided without the first element.

One aspect of the present disclosure provides an electric work machine including a motor, a circuit board, a first semiconductor switch, a second semiconductor switch, a first conductive trace, a second conductive trace, and a solid metal component. The motor is configured to receive electric power from a power supply to thereby be driven. The circuit board includes a first circuit surface, a second circuit surface opposite the first circuit surface, and a through-hole. The first semiconductor switch is electrically coupled to the power supply and to the motor, is mounted on the first circuit surface, and includes a first terminal. The second semiconductor switch is electrically coupled to the power supply and to the motor, is mounted on the second circuit surface, is distinct from the first semiconductor switch, and includes a second terminal. The first conductive trace is arranged on the first circuit surface, and is electrically coupled to the first terminal. The second conductive trace is arranged on the second circuit surface, and is electrically coupled to the second terminal. The solid metal component is inserted into the through-hole, and is electrically coupled to the first conductive trace and to the second conductive trace.

In such an electric work machine, the first terminal is electrically coupled to the second terminal via the solid metal component inserted into the through-hole. Since the width of the metal component can be made larger than a via diameter, the width of each of the first and second conductive traces can be made larger. This in turn makes it possible to reduce the inductance of each of the first and second conductive traces. Moreover, since the metal component is solid, the inductance of the metal component can be made lower than that of the via. Accordingly, it is possible to reduce the inductance of the current path on the circuit board, thus suppressing the surge voltages generated in association with the switching operations of the first and second semiconductor switches. This results in allowing the rated voltages of the first and second semiconductor switches to be lower, thus reducing the heat generation in the first and second semiconductor switches. Furthermore, such a reduction in the heat generation in the first and second semiconductor switches enables a size reduction of the components on the circuit board and the heat dissipation member of the electric work machine. This ultimately enables a reduction in the size of the electric work machine.

Another aspect of the present disclosure provides a method for assembling a drive unit for driving a motor of an electric work machine. This method includes: mounting a first semiconductor switch of the drive unit on a first circuit surface of a circuit board of the drive unit, the first circuit surface including a first conductive trace; mounting a second semiconductor switch of the drive unit distinct from the first semiconductor switch on a second circuit surface opposite the first circuit surface of the circuit board, the second circuit surface including a second conductive trace; inserting a solid metal component into a through-hole included in the circuit board; electrically coupling a first terminal of the first semiconductor switch to the first conductive trace; electrically coupling a second terminal of the second semiconductor switch to the second conductive trace; and electrically coupling the first conductive trace and the second conductive trace to the solid metal component.

According to such a method, it is possible to reduce the inductance of the current path on the circuit board of the electric work machine, thus suppressing the surge voltages generated in association with the switching operations of the first and second semiconductor switches.

### BRIEF DESCRIPTION OF THE DRAWINGS

Example embodiments of the present disclosure will be described hereinafter with reference to the accompanying drawings, in which:

FIG. 1 is a view showing an external appearance of an electric work machine according to the present embodiment;

FIG. 2 is a diagram showing an electrical configuration of the electric work machine according to the present embodiment;

FIG. 3 is a view showing a first circuit surface of a circuit board on which a drive circuit according to the present embodiment is mounted;

FIG. 4 is a view showing a second circuit surface of the circuit board according to the present embodiment;

FIG. 5 is a view showing an external appearance of a metal component to be inserted into the circuit board according to the present embodiment;

FIG. 6 is a view showing electrical coupling between a source terminal of a first semiconductor switch and a drain terminal of a fourth semiconductor switch, according to the present embodiment;

FIG. 7 is a view showing a longitudinal cross-section of the circuit board according to the present embodiment; and

FIG. 8 is a view showing a longitudinal cross-section, in a modified example, of the circuit board according to the present embodiment.

FIG. 9 is a partial longitudinal cross-sectional view of a drive unit according to another embodiment.

### DETAILED DESCRIPTION OF EXEMPLARY EMBODIMENTS

### Overview of Embodiments

One embodiment may provide an electric work machine including at least any one of:
Feature 1: a motor configured to receive electric power from a power supply to thereby be driven;
Feature 2: a circuit board including a first circuit surface, a second circuit surface opposite the first circuit surface, and a through-hole;
Feature 3: a first semiconductor switch electrically coupled to the power supply and to the motor and mounted on the first circuit surface;
Feature 4: the first semiconductor switch includes a first terminal;
Feature 5: a second semiconductor switch electrically coupled to the power supply and to the motor, mounted on the second circuit surface, and distinct from the first semiconductor switch;
Feature 6: the second semiconductor switch includes a second terminal;
Feature 7: a first conductive trace arranged on the first circuit surface and electrically coupled to the first terminal;
Feature 8: a second conductive trace arranged on the second circuit surface and electrically coupled to the second terminal;
Feature 9: a solid metal component inserted into the through-hole; and
Feature 10: the solid metal component is electrically coupled to the first conductive trace and to the second conductive trace.

In the electric work machine including at least Features 1 through 10, the first terminal is electrically coupled to the second terminal via the solid metal component inserted into the through-hole. Since the width of the metal component can be made larger than a via diameter, the width of each of the first and second conductive traces can be made larger. This in turn makes it possible to reduce the inductance of each of the first and second conductive traces. Moreover, since the metal component is solid, the inductance of the metal component can be made lower than that of the via. Accordingly, it is possible to reduce the inductance of the current path on the circuit board, thus suppressing the surge voltages generated in association with the switching operations of the first and second semiconductor switches. This results in allowing the rated voltages of the first and second semiconductor switches to be lower, thus reducing the heat generation in the first and second semiconductor switches. Furthermore, such a reduction in the heat generation in the first and second semiconductor switches enables a size reduction of the components on the circuit board and the heat dissipation member of the electric work machine. This ultimately enables a reduction in the size of the electric work machine.

Examples of the solid metal component include, but are not limited to, a solid metal component manufactured in advance, and conductive paste or solder that is filled into the through-hole and then hardened or sintered. Examples of the conductive paste include, but are not limited to, metal paste, more specifically, gold paste, silver paste, copper paste, or aluminum paste.

One embodiment may include, in addition to or in place of at least any one of Features 1 through 10, at least one of:
Feature 11: the first semiconductor switch corresponds to a high-side switch of a drive circuit for driving the motor;
Feature 12: the second semiconductor switch corresponds to a low-side switch of the drive circuit; and
Feature 13: the first terminal faces the second terminal via the circuit board.

In the electric work machine including at least Features 1 through 13, the first terminal of the high-side switch faces the second terminal of the low-side switch via the circuit board. Thus, the first and second conductive traces on the current path from the first terminal to the second terminal each can have a reduced length. This in turn makes it possible to further reduce the inductance component of the circuit board, thus further suppressing the surge voltages generated in association with the switching operations of the first and second semiconductor switches.

One embodiment may include, in addition to or in place of at least any one of Features 1 through 13, at least one of:
Feature 14: the first semiconductor switch and the second semiconductor switch are each a field-effect transistor;
Feature 15: the first terminal is a source terminal of the first semiconductor switch; and
Feature 16: the second terminal is a drain terminal of the second semiconductor switch.

In the electric work machine including at least Features 1 through 10 and 14 through 16, the source terminal of the high-side switch can be coupled to the drain terminal of the low-side switch via the first and second conductive traces each having a reduced length.

One embodiment may include, in addition to or in place of at least any one of Features 1 through 16, at least one of:
Feature 17: the solid metal component includes: a first part protruding from the through-hole; and a second part accommodated in the through-hole;
Feature 18: the through-hole has a first length in a specified direction along the first circuit surface;
Feature 19: the first part has a second length greater than the first length in the specified direction; and
Feature 20: the second part has a third length smaller than the first length in the specified direction.

In the electric work machine including at least Features 1 through 10 and 17 through 20, the second length is greater than the first length, and the third length is smaller than the first length. Thus, the second part is accommodated in the through-hole, and part of the lower surface of the first part is in contact with the first circuit surface. This makes it possible to inhibit the solid metal component from coming off from the circuit board.

One embodiment may include, in addition to or in place of at least any one of Features 1 through 20,
Feature 21: the through-hole extends along an end of the first semiconductor switch.

In the electric work machine including at least Features 1 through 10 and 21, the through-hole extends along the end of the first semiconductor switch. Thus, the through-hole can be arranged in the close vicinity of the first and second semiconductor switches. This in turn makes it possible to further reduce the lengths of the first and second conductive traces on the current path from the first terminal to the second terminal, thus further suppressing the surge voltages generated in association with the switching operations of the first and second semiconductor switches.

One embodiment may include, in addition to or in place of at least any one of Features 1 through 21,
Feature 22: the through-hole has a rectangular parallelepiped shape.

In the electric work machine including at least Features 1 through 10, 21, and 22, the volume of the metal component can be larger to thereby reduce the inductance of the metal component, while inhibiting the circuit board from being larger.

One embodiment may include, in addition to or in place of at least any one of Features 1 through 22, at least one of:
Feature 23: the first semiconductor switch and the second semiconductor switch each have a rectangular parallelepiped shape;
Feature 24: a transverse direction of the first semiconductor switch is aligned with a transverse direction of the second semiconductor switch; and
Feature 25: a longitudinal direction of the through-hole is aligned with the transverse direction of the first semiconductor switch and the transverse direction of the second semiconductor switch.

In the electric work machine including at least Features 1 through 10 and 21 through 25, the inductances of the first and second conductive traces and of the metal component can be reduced while inhibiting the circuit board from being larger.

One embodiment may include, in addition to or in place of at least any one of Features 1 through 25,
Feature 26: a solder resist applied to an area, on the first conductive trace, between the end of the first semiconductor switch and the through-hole.

In the electric work machine including at least Features 1 through 10, 21, and 26, the solder resist is applied to the area between the end of the first semiconductor switch and the through-hole. This makes it possible to avoid contact between the solder joining the solid metal component to the first conductive trace and the solder joining the first terminal to the first conductive trace.

At least one of the first and second semiconductor switches may include a surface-mount package, more specifically, a top-side cooling package or a dual-side cooling package (or a double-sided cooling package). Examples of the top-side cooling package include, but are not limited to, TO-Leaded Top-side cooling (TOLT) package. Examples of the dual-side cooling package include, but are not limited to, Double-side-cooling Small Outline Package (DSOP). Examples of the first and semiconductor switches include, but are not limited to, a metal-oxide-semiconductor field-effect transistor (MOSFET), a junction field-effect transistor (JFET), an insulated-gate bipolar transistor (IGBT), a bipolar transistor, a solid-state relay (SSR), and a thyristor.

Examples of the electric work machine include, but are not limited to, various electric apparatuses used in job sites of do-it-yourself carpentry, manufacturing, horticulture, gardening, construction, and so on, specifically, electric power tools for masonry work, metalworking, and woodworking, work machines for gardening, and devices for creating an environment of job sites, and more specifically, electric blowers, electric hammers, electric hammer drills, electric drills, electric drivers, electric wrenches, electric grinders, electric polishers, electric circular saws, electric reciprocating saws, electric jig saws, electric cutters, electric chain saws, electric planes, electric nailing machines (including electric tackers), electric hedge trimmers, electric lawn mowers, electric lawn trimmers, electric bush/grass cutters, electric cleaners, electric sprayers, electric spreaders, electric dust collectors (or electric dust extractors), electric bicycles (or e-bikes), and battery-powered wheel barrows (or battery-powered dollies).

One embodiment may provide a method for assembling a drive unit for driving a motor of an electric work machine, the method including at least any one of:
Feature 27: mounting a first semiconductor switch of the drive unit on a first circuit surface of a circuit board of the drive unit;
Feature 28: the first circuit surface includes a first conductive trace;
Feature 29: mounting a second semiconductor switch of the drive unit distinct from the first semiconductor switch on a second circuit surface opposite the first circuit surface of the circuit board;
Feature 30: the second circuit surface includes a second conductive trace;
Feature 31: inserting a solid metal component into a through-hole included in the circuit board;
Feature 32: electrically coupling a first terminal of the first semiconductor switch to the first conductive trace;
Feature 33: electrically coupling a second terminal of the second semiconductor switch to the second conductive trace; and
Feature 34: electrically coupling the first conductive trace and the second conductive trace to the solid metal component.

According to the method including at least Features 27 through 34, it is possible to reduce the inductance of the circuit board of the electric work machine, thus suppressing the surge voltages generated in association with the switching operations of the first and second semiconductor switches.

In one embodiment, Features 1 through 34 may be combined in any combination.

In one embodiment, any of Features 1 through 34 may be excluded.

### Specific Example Embodiments

Specific example embodiments will be described below. These specific example embodiments provide an electric work machine 1 in the form of an electric chain saw. The electric chain saw is a kind of gardening tool. However, the electric work machine 1 of this kind is merely an example, and the present disclosure can be applied to electric work machines in any forms.

### 1. Embodiment

### 1-1. Configuration of Electric Work Machine

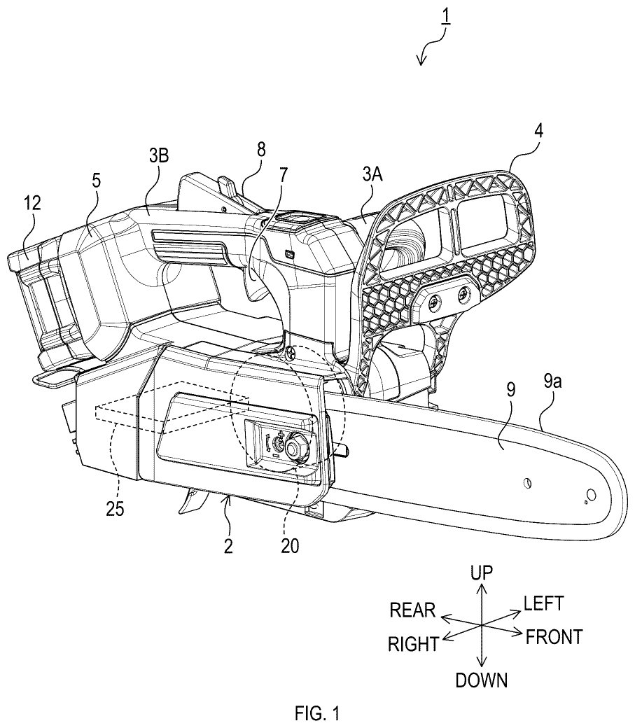

As shown in FIG. 1, the electric work machine 1 includes a housing 2. The housing 2 is made of synthetic resin. The housing 2 houses a motor 20. The housing 2 also houses a drive unit 25. The drive unit 25 includes: a circuit board 11; and a drive circuit 21 mounted on the circuit board 11, which will both be described below.

The words “upper”, “lower”, “front”, “rear”, “left”, and “right” in the descriptions below are used merely to facilitate easy understanding of the structures of the electric work machine 1 and its components, and are not intended to limit the orientations of the electric work machine 1 and its components. The electric work machine 1 and its components may be arranged in any orientation.

The electric work machine 1 includes a guide bar 9. The guide bar 9 is a plate-shaped member. The guide bar 9 protrudes from the housing 2 in a forward direction of the electric work machine 1.

The electric work machine 1 includes a saw chain 9a as a tool. The saw chain 9a includes multiple cutters connected to each other. The saw chain 9a is detachably attached to a peripheral edge of the guide bar 9. The saw chain 9a is coupled to a rotor shaft (not shown) of the motor 20 via a power transmission mechanism (not shown). The power transmission mechanism includes a sprocket (not shown) configured to receive the saw chain 9a thereon.

Thus, driving the motor 20 causes the saw chain 9a to move along the peripheral edge of the guide bar 9. Such movement of the saw chain 9a enables the electric work machine 1 to cut a workpiece.

The electric work machine 1 includes a battery attachment portion 5. The battery attachment portion 5 of the present embodiment protrudes upward from a rear part of the housing 2. The battery attachment portion 5 is where a battery pack 12 is detachably attached. The battery pack 12 is attachable to a rear end face of the battery attachment portion 5. The battery pack 12 includes a rechargeable battery. In the present embodiment, the rechargeable battery is a lithium-ion battery, but is not limited thereto. By being attached to the battery attachment portion 5, the battery pack 12 can supply DC power to the electric work machine 1.

In another embodiment, the electric work machine 1 may include a power cord in place of the battery attachment portion 5. The electric work machine 1 may receive AC power from an AC power supply, such as utility power (or AC mains), via the power cord. The AC power received from the AC power supply may be converted into DC power or into AC power with different characteristics in the electric work machine 1.

The electric work machine 1 includes a hand guard 4. The hand guard 4 protrudes upward from a front part of the housing 2.

The electric work machine 1 includes a side handle 3A and a top handle 3B positioned rearward of the hand guard 4. Either the side handle 3A or the top handle 3B may be omitted. The side handle 3A and the top handle 3B are made of synthetic resin.

The side handle 3A is a tubular member. The side handle 3A protrudes leftward from a left part of the housing 2. Thus, a user of the electric work machine 1 can grip the side handle 3A with the user's left hand from the rear of the electric work machine 1.

The top handle 3B protrudes upward from an upper part of the housing 2. A rear end of the top handle 3B is coupled to the battery attachment portion 5, thus forming a space between the top handle 3B and the housing 2. This enables the user to grip the top handle 3B by inserting the user's fingers through this space.

The electric work machine 1 includes a trigger switch 7 on the lower portion the top handle 3B. The trigger switch 7 is configured to be operated (e.g., pulled) by the user to drive the motor 20. Pulling the trigger switch 7 upward by the user causes the motor 20 to be driven. Upon releasing the operation of the trigger switch 7, driving of the motor 20 is stopped.

The electric work machine 1 includes a trigger lock lever 8 on the upper portion of the top handle 3B. The user presses the trigger lock lever 8 downward to releases the lock on the trigger switch 7.

### 1-2. Control Unit

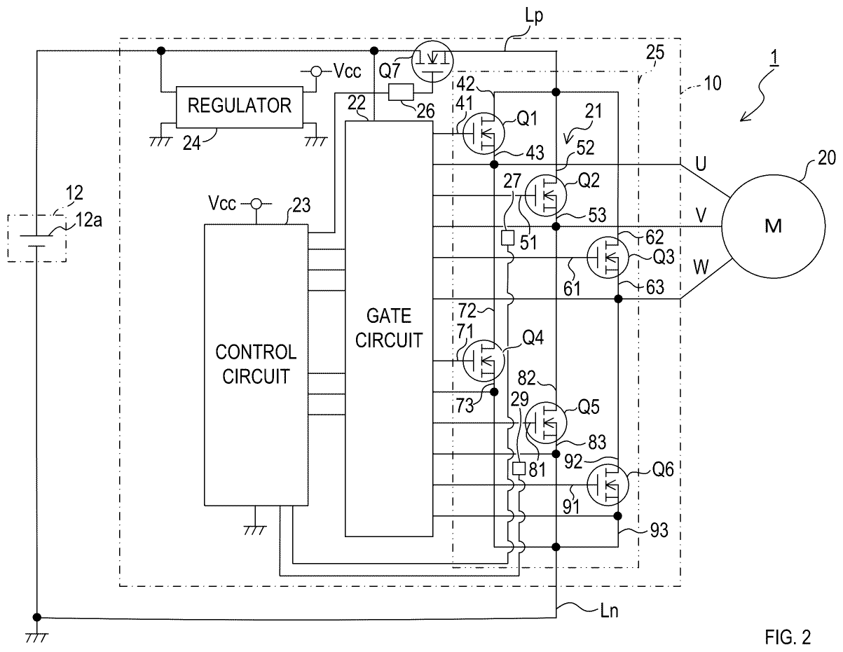

As shown in FIG. 2, the electric work machine 1 includes a control unit 10. The control unit 10 receives the DC power from a battery 12a within the battery pack 12 and controls the motor 20 so as to drive or stop the saw chain 9a. In the present embodiment, the motor 20 is a three-phase brushless DC motor. In another embodiment, the motor 20 may be a single-phase brushless DC motor, a two-phase brushless DC motor, a brushless DC motor with four or more phases, a brushed motor, an AC motor, or a stepper motor.

The control unit 10 includes: the drive unit 25 including a drive circuit 21; a gate circuit 22; a control circuit 23; and a regulator 24.

The drive circuit 21 is configured (i) to receive a DC motor current from the battery 12a, (ii) to convert the received DC motor current into three-phase AC motor currents (i.e., U-phase, V-phase, and W-phase motor currents), and (iii) to supply the three-phase AC motor currents to the three-phase windings of the motor 20. Specifically, the drive circuit 21 is a three-phase full-bridge inverter circuit including first through sixth semiconductor switches Q1 through Q6. In another embodiment, the drive circuit 21 may be a full-bridge inverter circuit with a single phase, two phases, or four or more phases, or may be a half-bridge inverter circuit.

Specifically, the first through sixth semiconductor switches Q1 through Q6 are FETs. More specifically, the first through sixth semiconductor switches Q1 through Q6 are N-channel MOSFETs. In another embodiment, at least one of the first through sixth semiconductor switches Q1 through Q6 may be a P-channel MOSFET, a JFET, an IGBT, a bipolar transistor, an SSR, or a thyristor.

In the drive circuit 21, the first through third semiconductor switches Q1 through Q3 are high-side switches. The first through third semiconductor switches Q1 through Q3 are respectively coupled to terminals U, V, and W of the motor 20 and to a power line Lp. The power line Lp is coupled to a positive electrode of the battery 12a. In the drive circuit 21, the fourth through sixth semiconductor switches Q4 through Q6 are low-side switches. The fourth through sixth semiconductor switches Q4 through Q6 are respectively coupled to the terminals U, V, and W of the motor 20 and to a ground line Ln. The ground line Ln is coupled to a negative electrode of the battery 12a.

The first through sixth semiconductor switches Q1 through Q6 include gate terminals 41, 51, 61, 71, 81, and 91; drain terminals 42, 52, 62, 72, 82, and 92; and source terminals 43, 53, 63, 73, 83, and 93, respectively. The gate terminals 41, 51, 61, 71, 81, and 91 of the first through sixth semiconductor switches Q1 through Q6 are coupled to the gate circuit 22. The drain terminals 42, 52, and 62 of the first through third semiconductor switches Q1 through Q3 are coupled to the power line Lp. The source terminals 73, 83, and 93 of the fourth through sixth semiconductor switches Q4 through Q6 are coupled to the ground line Ln. The source terminal 43 of the first semiconductor switch Q1 is coupled to the drain terminal 72 of the fourth semiconductor switch Q4 and to a U-phase of the motor 20. The source terminal 53 of the second semiconductor switch Q2 is coupled to the drain terminal 82 of the fifth semiconductor switch Q5 and to a V-phase of the motor 20. The source terminal 63 of the third semiconductor switch Q3 is coupled to the drain terminal 92 of the sixth semiconductor switch Q6 and to a W-phase of the motor 20.

The gate circuit 22 turns on or off the first through sixth semiconductor switches Q1 through Q6 in accordance with control signals supplied from the control circuit 23 to supply the three-phase AC motor currents to the three-phase windings of the motor 20. This results in rotating the motor 20.

The control circuit 23 includes a not-shown microcomputer (or microcontroller, or microprocessor). In another embodiment, the control circuit 23 may include an additional microcomputer. In still another embodiment, the control circuit 23 may include, in place of or in addition to the microcomputer, a graphics processing unit (GPU), a hardwired logic, an application specific integrated circuit (ASIC), an application specific standard product (ASSP), a programmable logic device (PLD) (e.g., a field programmable gate array (FPGA)), a discrete electronic component, and/or a combination thereof.

The regulator 24 is configured (i) to receive the DC power from the battery 12a and (ii) to generate a power-supply voltage Vcc. The power-supply voltage Vcc is supplied to internal circuits of the control unit 10, including the control circuit 23.

The control unit 10 further includes a load switch Q7 and a bootstrap 26. The load switch Q7 is disposed between the battery 12a and the drive circuit 21 on the power line Lp in order to protect the drive circuit 21 and/or the motor 20. The load switch Q7 is a semiconductor switch. Specifically, the load switch Q7 is an N-channel MOSFET. In another embodiment, the load switch Q7 may be a P-channel MOSFET, a JFET, an IGBT, a bipolar transistor, or an SSR. In still another embodiment, the load switch Q7 may be a mechanical relay. A gate terminal of the load switch Q7 is coupled to the control circuit 23 via the bootstrap 26. The load switch Q7 is maintained to be ON while driving of the motor 20 is permitted. The motor current flowing through the load switch Q7 can be larger than the motor current flowing through each of the first through sixth semiconductor switches Q1 through Q6. The voltage applied to the load switch Q7 can be larger than the voltage applied to each of the first through sixth semiconductor switches Q1 through Q6. Thus, the rated voltage and the rated current of the load switch Q7 are higher than those of the first through sixth semiconductor switches Q1 through Q6.

The drive circuit 21 includes first and second thermistors 27 and 29. The first thermistor 27 is disposed in the vicinity of the first through third semiconductor switches Q1 through Q3 to measure the temperature near the first through third semiconductor switches Q1 through Q3. The first thermistor 27 supplies, to the control circuit 23, a temperature detection signal indicating the measured temperature. The second thermistor 29 is disposed in the vicinity of the fourth through sixth semiconductor switches Q4 through Q6 to measure the temperature near the fourth through sixth semiconductor switches Q4 through Q6. The second thermistor 29 supplies, to the control circuit 23, a temperature detection signal indicating the measured temperature.

### 1-3. Drive Unit

### 1-3-1. Examples

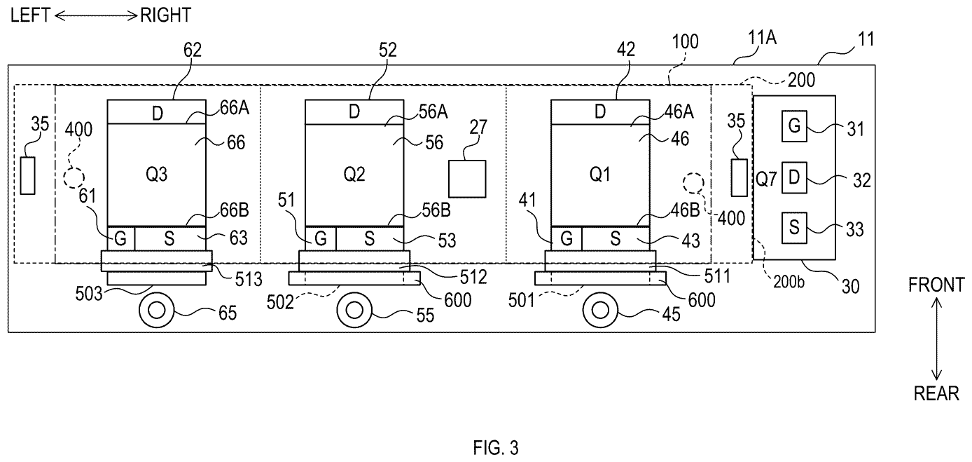

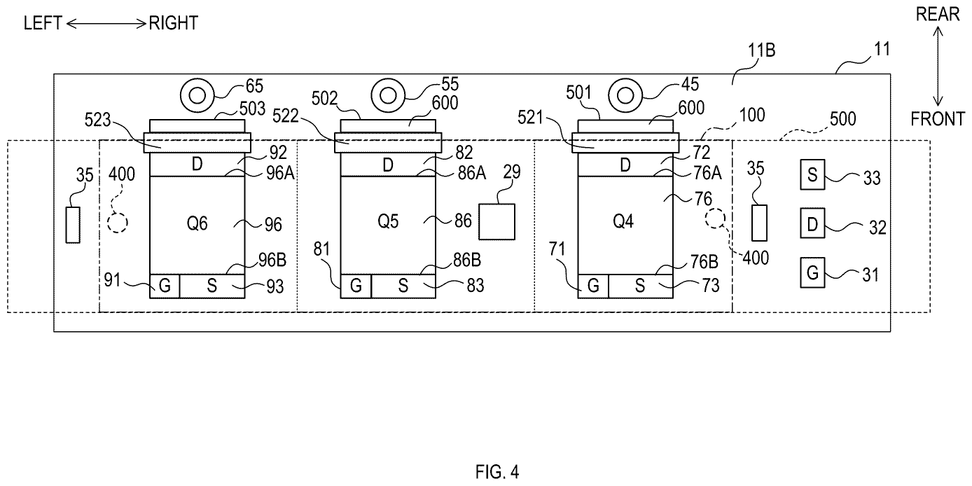

The drive unit 25 will be described with reference to FIGS. 3 through 7. The drive unit 25 includes: the circuit board 11; the drive circuit 21 mounted on the circuit board 11; four elastic members 35; two metal plates 100; heat dissipation members 200 and 500; four male screws 400; three metal components 600; first through third printed wirings 511 through 513; and fourth through sixth printed wirings 521 through 523. FIGS. 3 and 4 show the two metal plates 100, the heat dissipation members 200 and 500, and the four male screws 400 in a transparent manner. In practice, the drive circuit 21 on the circuit board 11 is covered by the two metal plates 100 and the heat dissipation members 200 and 500.

The circuit board 11 is a printed circuit board (PCB). The circuit board 11 has a rectangular planar shape. In another embodiment, the circuit board 11 may have a planar shape not rectangular. The circuit board 11 includes a first circuit surface 11A and a second circuit surface 11B. The second circuit surface 11B is disposed opposite the first circuit surface 11A.

The drive circuit 21 includes the first through sixth semiconductor switches Q1 through Q6, the first and second thermistors 27 and 29, the U-phase terminal 45, the V-phase terminal 55, the W-phase terminal 65, three metal components 600, first through third printed wirings 511 through 513, and fourth through sixth printed wirings 521 through 523.

The first through sixth semiconductor switches Q1 through Q6 are of a surface-mount type. In other words, the first through sixth semiconductor switches Q1 through Q6 each have a surface-mount package. Specifically, the first through sixth semiconductor switches Q1 through Q6 each have a top-side cooled package, more specifically, a TOLT package. The first through sixth semiconductor switches Q1 through Q6 are of the same model, but are not limited to being of the same model.

The respective packages of the first through sixth semiconductor switches Q1 through Q6 are plate-shaped, and include (i) first ends 46A, 56A, 66A, 76A, 86A, and 96A and (ii) second ends 46B, 56B, 66B, 76B, 86B, and 96B opposite the respective first ends. The drain terminals 42, 52, 62, 72, 82, and 92 of the first through sixth semiconductor switches Q1 through Q6 protrude from the respective first ends 46A, 56A, 66A, 76A, 86A, and 96A. The gate terminals 41, 51, 61, 71, 81, and 91 of the first through sixth semiconductor switches Q1 through Q6 protrude from the respective second ends 46B, 56B, 66B, 76B, 86B, and 96B. The source terminals 43, 53, 63, 73, 83, and 93 of the first through sixth semiconductor switches Q1 through Q6 protrude from the respective second ends 46B, 56B, 66B, 76B, 86B, and 96B.

The first semiconductor switch Q1 includes (i) a first metal surface 46 and (ii) a first mount surface 48 opposite the first metal surface 46. The second semiconductor switch Q2 includes (i) a second metal surface 56 and (ii) a second mount surface 58 opposite the second metal surface 56. The third semiconductor switch Q3 includes (i) a third metal surface 66 and (ii) a third mount surface 68 opposite the third metal surface 66. The fourth semiconductor switch Q4 includes (i) a fourth metal surface 76 and (ii) a fourth mount surface 78 (not shown in FIGS. 3 and 4) opposite the fourth metal surface 76. The fifth semiconductor switch Q5 includes (i) a fifth metal surface 86 and (ii) a fifth mount surface 88 (not shown in FIGS. 3 and 4) opposite the fifth metal surface 86. The sixth semiconductor switch Q6 includes (i) a sixth metal surface 96 and (ii) a sixth mount surface 98 (not shown in FIGS. 3 and 4) opposite the sixth metal surface 96.

The first through sixth metal surfaces 46, 56, 66, 76, 86, and 96 include respective metal plates (metal pads) joined to respective surfaces of the packages of the first through sixth semiconductor switches Q1 through Q6. The metal plates contain aluminum, copper, silver, or gold, or are made of aluminum, copper, silver, or gold. The first through sixth semiconductor switches Q1 through Q6 are mounted on the first circuit surface 11A such that the first through sixth mount surfaces 48, 58, 68, 78, 88, and 98 face the first circuit surface 11A. The first through sixth mount surfaces 48, 58, 68, 78, 88, and 98 are soldered to the first circuit surface 11A.

As shown in FIG. 3, the first through third semiconductor switches Q1 through Q3 are arranged in a row along the longitudinal direction (left-right) on the first circuit surface 11A. The first through third semiconductor switches Q1 through Q3 are arranged such that the first ends 46A, 56A, and 66A are on the front side and such that the second ends 46B, 56B, and 66B are on the rear side.

As shown in FIG. 4, the fourth through sixth semiconductor switches Q4 through Q6 are arranged in a row along the longitudinal direction (left-right) on the second circuit surface 11B. The fourth through sixth semiconductor switches Q4 through Q6 are opposite the first through third semiconductor switches Q1 through Q3, respectively, via the circuit board 11. The fourth through sixth semiconductor switches Q4 through Q6 are arranged such that the second ends 76B, 86B, and 96B are on the front side and such that the first ends 76A, 86A, and 96A are on the rear side.

Accordingly, the source terminal 43 of the first semiconductor switch Q1 is opposite the drain terminal 72 of the fourth semiconductor switch Q4 via the circuit board 11. The source terminal 53 of the second semiconductor switch Q2 is opposite the drain terminal 82 of the fifth semiconductor switch Q5 via the circuit board 11. The source terminal 63 of the third semiconductor switch Q3 is opposite the drain terminal 92 of the sixth semiconductor switch Q6 via the circuit board 11.

The circuit board 11 includes first through third board through-holes 501 through 503 passing through the circuit board 11. The first through third board through-holes 501 through 503 are slits extending in the longitudinal direction (left-right). The first through third board through-holes 501 through 503 are disposed in the immediate vicinity of the respective source terminals 43, 53, and 63 and of the respective gate terminals 41, 51, and 61 (e.g., within 10 millimeters from the respective terminals) along the respective second ends 46B, 56B, and 66B of the first through third semiconductor switches Q1 through Q3. Accordingly, the first through third board through-holes 501 through 503 are disposed in the immediate vicinity of the drain terminals 72, 82, and 92, respectively, along the respective first ends 76A, 86A, and 96A of the fourth through sixth semiconductor switches Q4 through Q6.

The length of each of the first through third board through-holes 501 through 503 in the longitudinal direction (left-right) is substantially equal to the width of at least corresponding one of the first through sixth semiconductor switches Q1 through Q6 in the longitudinal direction (left-right) (e.g., 10 mm or more). In another embodiment, the respective planar shapes of the first through third board through-holes 501 through 503 may be elliptical, circular, or polygonal.

The metal components 600 are each inserted into a corresponding one of the first through third board through-holes 501 through 503. In FIGS. 3 and 4, for convenience, the first and second board through-holes 501 and 502 have the respective metal components 600 inserted therein and the other metal component 600 is removed from the third board through-hole 503. In practice, all of the first through third board through-holes 501 through 503 are filled with the respective metal components 600.

The metal components 600 contain metal with relatively high electrical conductivity, or are made of such metal. Examples of such metal include copper, silver, gold, and aluminum. The metal components 600 are solid members manufactured in advance. In another embodiment, at least one of the three metal components 600 may be made of conductive paste that is filled into any of the first through third board through-holes 501 through 503 and then hardened or sintered. The conductive paste may be metal paste, more specifically, gold paste, silver paste, copper paste, or aluminum paste. In still another embodiment, at least one of the three metal components 600 may be made of solder that is filled into any of the first through third board through holes 501 through 503 and then solidified.

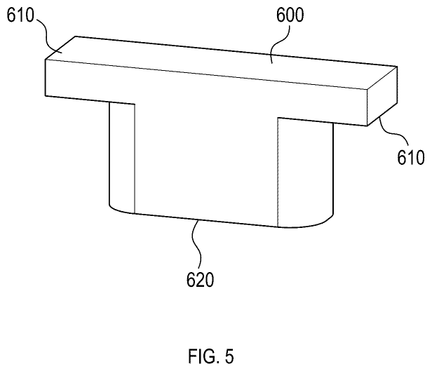

As shown in FIG. 5, the metal components 600 each include a first part 610 and a second part 620. The first part 610 has a substantially rectangular parallelepiped shape. In a horizontal planar view, the size of the first part 610 in its longitudinal direction is larger than that of each of the first through third board through-holes 501 through 503 in the longitudinal direction (left-right) of the circuit board 11. In a horizontal planar view, the size of the first part 610 in its lateral direction is slightly smaller than that of each of the first through third board through-holes 501 through 503 in the lateral direction (front-rear) of the circuit board 11, but may be the same as or larger than that. The second part 620 has a shape similar to a rectangular parallelepiped. In a horizontal planar view, the second part 620 is connected to a lower face of the first part 610 such that the longitudinal direction of the second part 620 is aligned with the longitudinal direction of the first part 610. The size of the second part 620 in its longitudinal direction is slightly smaller than that of each of the first through third board through-holes 501 through 503 in the longitudinal direction (left-right) of the circuit board 11. That is, the width of the second part 620 (e.g., 10 mm) is sufficiently greater than a via diameter (e.g., 0.5 mm). Here, the width corresponds to the length in a direction perpendicular to a direction in which electric current flows in a horizontal planar view, and the direction perpendicular to the direction in which electric current flows corresponds to the longitudinal direction. The height of the second part 620 is substantially equal to the thickness of the circuit board 11. The metal components 600 each have a T-shaped vertical cross-section but may have a vertical cross-section of another shape.

The metal components 600 are each inserted into a corresponding one of the first through third board through-holes 501 through 503 from the first circuit surface 11A toward the second circuit surface 11B. The first parts 610 each engage with the first circuit surface 11A, thereby inhibiting the corresponding metal component 600 from coming off from the circuit board 11. The second parts 620 are each accommodated in a corresponding one of the first through third board through-holes 501 through 503.

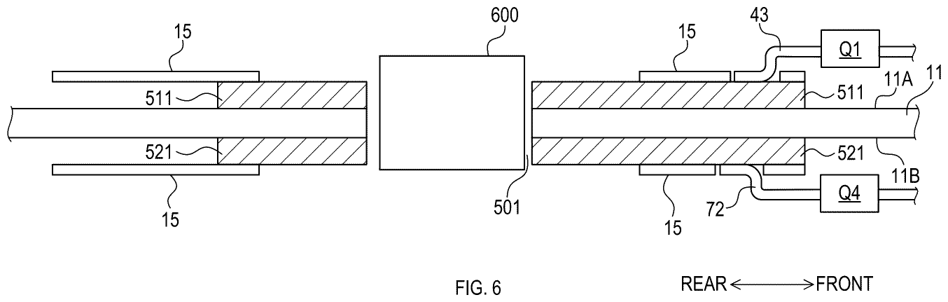

As shown in FIGS. 3 and 6, each of the first through third printed wirings 511 through 513 is disposed between a corresponding one of the source terminals 43, 53, and 63 of the first through third semiconductor switches Q1 through Q3 and a corresponding one of the first through third board through-holes 501 through 503. In addition, each of the first through third printed wirings 511 through 513 is disposed on the rear side of a corresponding one of the first through third board through-holes 501 through 503.

The printed wirings are formed from metal foils having relatively high electrical conductivity. More specifically, the metal foils contain copper, silver, or gold. The vias are filled or plated with metal. The metal contains copper, silver, or gold.

The first through third printed wirings 511 through 513 are electrically coupled to the source terminals 43, 53, and 63, respectively. Specifically, the first through third printed wirings 511 through 513 are soldered to the source terminals 43, 53, and 63, respectively. In addition, the first through third printed wirings 511 through 513 are each electrically coupled to a corresponding one of the metal components 600. Specifically, the first through third printed wirings 511 through 513 are each soldered to the first part 610 of the corresponding metal component 600.

In areas between the source terminal 43 and the corresponding metal component 600, between the source terminal 53 and the corresponding metal component 600, and between the source terminal 63 and the corresponding metal component 600, solder resist 15 is applied onto the first through third printed wirings 511 through 513. In addition, in areas on the rear sides of the three metal components 600, the solder resist 15 is applied onto the first through third printed wirings 511 through 513. The solder resist 15 is not applied below the first through third mount surfaces 48, 58, and 68. Respective lower ends of the gate terminals 41, 51, and 61, the drain terminals 42, 52, and 62, and the source terminals 43, 53, and 63 are located a little above a corresponding one of the first through third mount surfaces 48, 58, and 68. If the solder resist 15 were applied below the first through third mount surfaces 48, 58, and 68, soldering of the gate terminals 41, 51, and 61, the drain terminals 42, 52, and 62, and the source terminals 43, 53, and 63 would be difficult.

As shown in FIGS. 4 and 6, each of the fourth through sixth printed wirings 521 through 523 is disposed between a corresponding one of the drain terminals 72, 82, 92 of the fourth through sixth semiconductor switches Q4 through Q6 and a corresponding one of the first through third board through-holes 501 through 503. In addition, each of the fourth through sixth printed wirings 521 through 523 is disposed on the rear side of a corresponding one of the first through third board through-holes 501 through 503.

The fourth through sixth printed wirings 521 through 523 are electrically coupled to the drain terminals 72, 82, and 92, respectively. Specifically, the fourth through sixth printed wirings 521 through 523 are soldered to the drain terminals 72, 82, and 92, respectively. In addition, the fourth through sixth printed wirings 521, 522, and 523 are each electrically coupled to a corresponding one of the metal components 600. Specifically, the fourth through sixth printed wirings 521 through 523 are each soldered to the second part 620 of the corresponding metal component 600. The metal components 600 are each electrically coupled to a corresponding one of the U-phase terminal 45, the V-phase terminal 55, and the W-phase terminal 65 via a corresponding one of the fourth through sixth printed wirings 521 through 523.

In areas between the drain terminal 72 and the corresponding metal component 600, between the drain terminal 82 and the corresponding metal component 600, and between the drain terminal 92 and the corresponding metal component 600, the solder resist 15 is applied onto the fourth through sixth printed wirings 521 through 523. In addition, in areas on the rear sides of the three metal components 600, the solder resist 15 is applied onto the fourth through sixth printed wirings 521 through 523. The solder resist 15 is not applied below the fourth through sixth mount surfaces 78, 88, and 98.

Each of the source terminals 43, 53, 63 of the first through third semiconductor switches Q1 through Q3 is electrically coupled to a corresponding one of the drain terminals 72, 82, 92 of the fourth through sixth semiconductor switches Q4 through Q6, via a corresponding one of the metal components 600. Thus, the lengths of the printed wirings from the source terminals 43, 53, and 63 to the respective drain terminals 72, 82, and 92 are suppressed to be minimum. This results in reducing the inductive component of the drive circuit 21. Accordingly, the surge voltages associated with the switching operations of the first through sixth semiconductor switches Q1 through Q6 are suppressed, thus allowing the rated voltages of the first through sixth semiconductor switches Q1 through Q6 to be lower. This furthermore enables reduction of heat generated in the first through sixth semiconductor switches Q1 through Q6. Consequently, at least one of the metal plates 100, the heat dissipation members 200 and 500 can be excluded or made smaller in size, and the electronic components on the circuit board 11 can be reduced in size. This in turn enables a reduction in the size and cost of the drive unit 25.

It is also possible to electrically couple the source terminals 43, 53, and 63 to the respective drain terminals 72, 82, and 92 through the printed wirings and the vias without using the metal components 600. However, in the case of coupling these terminals through the printed wirings and the vias, the printed wirings have to be longer, and the inductive component of the printed wirings can be increased. This in turn increases the surge voltages associated with the switching operations of the first through sixth semiconductor switches Q1 through Q6.

The first thermistor 27 is disposed, on the first circuit surface 11A, between the first semiconductor switch Q1 and the second semiconductor switch Q2. The second thermistor 29 is disposed, on the second circuit surface 11B, between the fourth semiconductor switch Q4 and the fifth semiconductor switch Q5. In the present example, the first through sixth semiconductor switches Q1 through Q6 each have a first height H1. The first and second thermistors 27 and 29 each have a second height H2. The first height H1 and the second height H2 each correspond to a length in a vertical direction (up-down), and the second height H2 is greater than the first height H1.

The U-phase terminal 45 is disposed, on the first circuit surface 11A, to the rear side of the first board through-hole 501. The source terminal 43 of the first semiconductor switch Q1, the drain terminal 72 of the fourth semiconductor switch Q4, the metal component 600 within the first board through-hole 501, and the U-phase terminal 45 are electrically coupled to each other. The drain terminal 42 of the first semiconductor switch Q1 is electrically coupled to the power line Lp through a not-shown printed wiring and/or a not-shown via on the first circuit surface 11A. The source terminal 73 of the fourth semiconductor switch Q4 is electrically coupled to the ground line Ln through a not shown printed wiring and/or a not-shown via on the second circuit surface 11B.

The V-phase terminal 55 is disposed, on the first circuit surface 11A, to the rear side of the second board through-hole 502. The source terminal 53 of the second semiconductor switch Q2, the drain terminal 82 of the fifth semiconductor switch Q5, the metal component 600 within the second board through-hole 502, and the V-phase terminal 55 are electrically coupled to each other. The drain terminal 52 of the second semiconductor switch Q2 is electrically coupled to the power line Lp through a not-shown printed wiring and/or a not-shown via on the first circuit surface 11A. The source terminal 83 of the fifth semiconductor switch Q5 is electrically coupled to the ground line Ln through a not-shown printed wiring and/or a not-shown via on the second circuit surface 11B.

The W-phase terminal 65 is disposed, on the first circuit surface 11A, to the rear side of the third board through-hole 503. The source terminal 63 of the third semiconductor switch Q3, the drain terminal 92 of the sixth semiconductor switch Q6, the metal component 600 within the third board through-hole 503, and the W-phase terminal 65 are electrically coupled to each other. The drain terminal 62 of the third semiconductor switch Q3 is electrically coupled to the power line Lp through a not-shown printed wiring and/or a not-shown via on the first circuit surface 11A. The source terminal 93 of the sixth semiconductor switch Q6 is electrically coupled to the ground line Ln through a not-shown printed wiring and/or a not-shown via on the second circuit surface 11B.

Each elastic member 35 is conductive. Specifically, the elastic member 35 is a formed spring made of metal, such as copper or aluminum. More specifically, the elastic member 35 has a vertical cross-section that is Z-shaped, but the vertical cross-sectional shape is not limited to Z-shape. In another embodiment, the elastic member 35 may be a coil spring made of metal. Alternatively, the elastic member 35 may be sponge with its surface coated with a conductive material.

Two of the elastic members 35 are disposed, on the first circuit surface 11A, to the right of the first semiconductor switch Q1 and to the left of the third semiconductor switch Q3. The rest of the elastic members 35 are disposed, on the second circuit surface 11B, to the right of the fourth semiconductor switch Q4 and to the left of the sixth semiconductor switch Q6. Each elastic member 35 includes (i) a first member surface 35A and (ii) a second member surface 35B opposite the first member surface 35A. The first member surface 35A is joined to the first circuit surface 11A or to the second circuit surface 11B with solder or the like.

Each metal plate 100 is a plate member having a rectangular shape. One of the metal plates 100 is arranged above the first circuit surface 11A such that its longitudinal direction is along the longitudinal direction (left-right) of the circuit board 11. The other of the metal plates 100 is arranged below the second circuit surface 11B such that its longitudinal direction is along the longitudinal direction (left-right) of the circuit board 11. One of the metal plates 100 is arranged to cover upper surfaces of the three high-side switches (i.e., the first through third semiconductor switches Q1 through Q3). The upper surfaces of the three high-side switches include the first through third metal surfaces 46, 56, and 66. The other of the metal plates 100 is arranged to cover upper surfaces of the three low-side switches (i.e., the fourth through sixth semiconductor switches Q4 through Q6). The upper surfaces of the three low-side switches include the fourth through sixth metal surfaces 76, 86, and 96. The metal plates 100 do not cover any of the four elastic members 35. The metal plates 100 are members for enhancing the dissipation of heat generated in the first through sixth semiconductor switches Q1 through Q6.

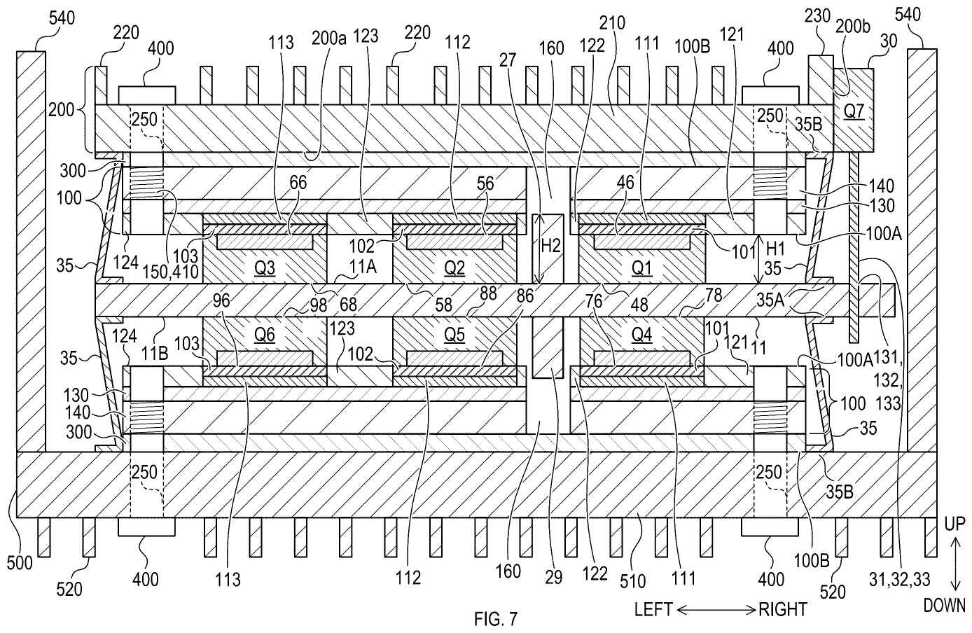

As shown in FIG. 7, the drive unit 25 has a structure that is vertically symmetrical with respect to the circuit board 11, except for the heat dissipation members 200 and 500. Thus, a structure above the circuit board 11 (i.e., a circuit structure of the high-side switches) will be described below. As for a structure below the circuit board 11 (i.e., a circuit structure of the low-side switches), the description of the structure above the circuit board 11 is applicable.

The metal plate 100 includes (i) a first plate surface 100A and (ii) a second plate surface 100B opposite the first plate surface 100A. The first plate surface 100A is joined to the first through third metal surfaces 46, 56, and 66 via solder. In another embodiment, the first plate surface 100A may be joined to the first through third metal surfaces 46, 56, and 66 via an adhesive with relatively high thermal conductivity. Examples of such an adhesive include silicon and epoxy resin.

The metal plate 100 includes a metal base 140, an insulating layer 130, first through third metal foils 111 through 113, a right insulating portion 121, first and second insulating portions 122 and 123, and a left insulating portion 124. The metal base 140 is a metal plate made of aluminum. That is, the metal base 140 is a metal plate with relatively high thermal conductivity and excellent heat dissipation. In another embodiment, the metal base 140 may be a metal plate made of another metal, such as copper. The metal base 140 may be any metal plate having excellent heat dissipation. An upper surface of the metal base 140 corresponds to the second plate surface 100B.

The insulating layer 130 is joined to a lower surface of the metal base 140. In detail, an upper surface of the insulating layer 130 is joined to the lower surface of the metal base 140 with an adhesive or the like. The insulating layer 130 contains a material having excellent electrical insulating and heat-dissipating properties, or is made of such a material. Examples of such a material include silicon and epoxy resin.

The first through third metal foils 111 through 113, the right insulating portion 121, the first and second insulating portions 122 and 123, and the left insulating portion 124 are joined to a lower surface of the insulating layer 130. The first through third metal foils 111 through 113, the right insulating portion 121, the first and second insulating portions 122 and 123, and the left insulating portion 124 form the first plate surface 100A. In other words, the first through third metal foils 111 through 113, the right insulating portion 121, the first and second insulating portions 122 and 123, and the left insulating portion 124 are included in the first plate surface 100A.

The first through third metal foils 111 through 113 are square-shaped metal foils (metal patches) and are, specifically, copper foils. The first through third metal foils 111 through 113 have approximately the same size as the first through third metal surfaces 46, 56, and 66, respectively. In another embodiment, the first through third metal foils 111 through 113 may be other metal foils, such as silver foils or gold foils.

The first metal foil 111 is arranged on the first plate surface 100A so as to face the first metal surface 46. The second metal foil 112 is arranged on the first plate surface 100A so as to face the second metal surface 56. The third metal foil 113 is arranged on the first plate surface 100A so as to face the third metal surface 66. That is, the first through third metal foils 111 through 113 are arranged side by side along the longitudinal direction (left-right) of the circuit board 11 at the same intervals as those of the first through third semiconductor switches Q1 through Q3.

The first metal foil 111 is joined to the first metal surface 46 via a solder layer 101. The second metal foil 112 is joined to the second metal surface 56 by a solder layer 102. The third metal foil 113 is joined to the third metal surface 66 via a solder layer 103. However, no electric current flows between the first through third metal foils 111 through 113 and the first through third metal surfaces 46, 56, and 66, respectively. The first through third metal foils 111 through 113 are provided on the first plate surface 100A for soldering the metal plate 100 to the first through third semiconductor switches Q1 through Q3. The first through third metal surfaces 46, 56, and 66 may be difficult to be soldered to the metal plate 100 depending on the kind of metal contained in the metal plate 100. Particularly, when the metal contained in the metal plate 100 is aluminum, it is difficult to achieve soldering. Inclusion of the first through third metal foils 111 through 113 in the first plate surface 100A enables the first through third metal surfaces 46, 56, and 66 to be soldered to the first plate surface 100A.

The solder layers 101 through 103 are each made of an alloy containing lead and/or tin, and have a higher thermal conductivity than resin or other materials. The first through third semiconductor switches Q1 through Q3 are joined to the metal plate 100 via the solder layers 101 through 103 having high thermal conductivity. Thus, a heat dissipation efficiency in heat dissipation paths from the first through third semiconductor switches Q1 through Q3 to the metal plate 100 can be improved compared with a case where the first through third semiconductor switches Q1 through Q3 are joined to the metal plate 100 with resin or another material.

In another embodiment, the first through third semiconductor switches Q1 through Q3 may be joined to the metal plate 100 via a thermal interface material (TIM), and the first through third metal foils 111 through 113 may be excluded from the metal plate 100. Examples of the TIM include thermal grease (or thermal paste), thermal adhesive, thermal sheet, thermal compound, and thermal putty.

The first and second insulating portions 122 and 123, the right insulating portion 121, and the left insulating portion 124 are solder resists (or solder masks) applied to the insulating layer 130. In another embodiment, the first and second insulating portions 122 and 123, the right insulating portion 121, and the left insulating portion 124 may be formed of an insulating material, or may contain an insulating material. Examples of the insulating material include silicon and epoxy resin.

The first insulating portion 122 is disposed between the first metal foil 111 and the second metal foil 112. The second insulating portion 123 is disposed between the second metal foil 112 and the third metal foil 113. The right insulating portion 121 is disposed to the right of the first metal foil 111. The left insulating portion 124 is disposed to the left of the third metal foil 113.

The metal plate 100 includes a plate through-hole 160 passing through the first insulating portion 122 and through the insulating layer 130 and the metal base 140 located above the first insulating portion 122. The plate through-hole 160 is aligned with the first thermistor 27 mounted on the first circuit surface 11A. Since the second height H2 is greater than the first height H1, the first thermistor 27 does not fit in a space between the first circuit surface 11A and the first insulating portion 122. Thus, the plate through-hole 160 is provided in the metal plate 100. The first thermistor 27 is partially accommodated in the plate through-hole 160.

The metal plate 100 has two female threads 150 formed therein. The female threads 150 each include a helical thread ridge. One of the female threads 150 is formed on an inner surface of a corresponding through-hole passing through the right insulating portion 121 and through the insulating layer 130 and the metal base 140 located above the right insulating portion 121. The other of the female threads 150 is formed on an inner surface of a corresponding through-hole passing through the left insulating portion 124 and through the insulating layer 130 and the metal base 140 located above the left insulating portion 124. In the present embodiment, the female threads 150 are each formed on the inner surfaces of the respective through-holes in the metal base 140. In another embodiment, either one of the female threads 150 may be formed on the inner surface of the corresponding through-hole in the metal base 140.

The second plate surface 100B is joined to an adhesive layer 300. One of the heat dissipation members 200 is in contact with the second plate surface 100B indirectly via the adhesive layer 300. The adhesive layer 300 is formed by applying, to the second plate surface 100B, a material having (i) adhesive properties and (ii) a thermal conductivity higher than that of air or by applying, to the second plate surface 100B, a sheet made of such a material. Specifically, the adhesive layer 300 is formed of the TIM, more specifically, of thermal compound. Typically, the second plate surface 100B has fine irregularities. A bottom surface of the heat dissipation member 200 also has fine irregularities. The adhesive layer 300 fills a gap between the second plate surface 100B and the bottom surface of the heat dissipation member 200 to thereby enhance a heat dissipation efficiency in a heat dissipation path from the metal plate 100 to the heat dissipation member 200. In another embodiment, the adhesive layer 300 and the heat dissipation member 200 may be excluded from the drive unit 25. In a case where a sufficient heat dissipation effect can be achieved by the metal plate 100 alone, the heat dissipation member 200 need not be joined to the metal plate 100.

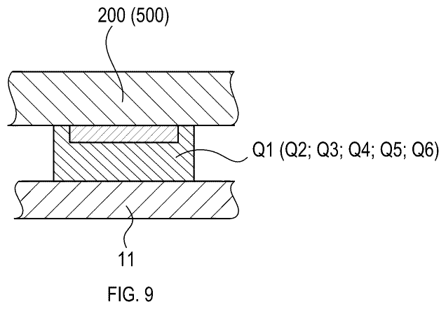

In another embodiment, the adhesive layer 300 may be excluded from the drive unit 25 and the heat dissipation member 200 may be directly joined to the second plate surface 100B. In still another embodiment, the metal plate 100 and the adhesive layer 300 may be excluded from the drive unit 25 (see FIG. 9). The bottom surface of the heat dissipation member 200 may include an insulating layer formed thereon, and three metal foils may be provided on the insulating layer. Then, the three metal foils may be soldered to the first through third metal surfaces 46, 56, and 66 of the first through third semiconductor switches Q1 through Q3.

The heat dissipation member 200 includes a right end part and a left end part, each in contact with the second member surface 35B of a corresponding one of the two elastic members 35. The heat dissipation member 200 is not fixed to the second member surfaces 35B, and is supported by the elastic force of the elastic members 35. Thus, assembly tolerances of the first through third semiconductor switches Q1 through Q3, the metal plate 100, the adhesive layer 300, and the heat dissipation member 200 are absorbed by the elastic members 35.

Since the elastic members 35 are conductive, the elastic members 35 electrically couples the circuit board 11 to the heat dissipation member 200. Thus, static electricity is inhibited from building up on the circuit board 11, thereby inhibiting a local voltage increase on the circuit board 11 caused by the static electricity and ultimately inhibiting damage to the electronic components on the circuit board 11 due to electrostatic discharge.

In another embodiment, the heat dissipation members 200 and 500 each may be supported by a single elastic member or by three or more elastic members. In addition, the drive unit 25 may include, in place of the two heat dissipation members 200 and 500, a single heat dissipation member that covers the upper surfaces of the first through sixth semiconductor switches Q1 through Q6. The single heat dissipation member may be supported by a single elastic member or by three or more elastic members. The single elastic member or each of the three elastic members may have a configuration similar to that of the elastic member 35.

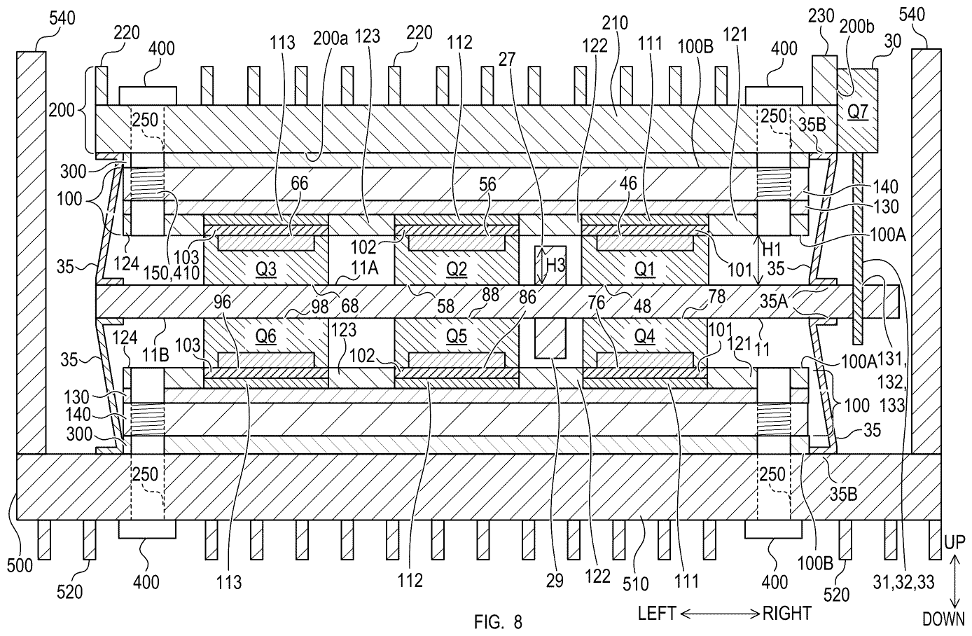

The heat dissipation member 200 is a heat sink made of metal, such as aluminum or copper. As shown in FIGS. 7 and 8, the heat dissipation member 200 includes a base 210, multiple fins 220, and an attachment portion 230. The base 210 is plate-shaped and is joined to the adhesive layer 300 so as to be substantially parallel to the circuit board 11 and the metal plate 100. The base 210 includes two insertion holes 250 passing through the base 210. The insertion holes 250 are each formed to face (or to be aligned with) a corresponding one of the female threads 150. No thread ridges are formed on respective inner surfaces of the insertion holes 250, and the inner surfaces are smooth.

The fins 220 are each plate-shaped. The fins 220 are coupled to the base 210 such that longitudinal directions thereof are along the lateral direction (front-rear) of the circuit board 11. The fins 220 are arranged in parallel with each other in the longitudinal direction (left-right) of the circuit board 11. In another embodiment, the fins 220 may be arranged in parallel with each other on the base 210 in the lateral direction (front-rear) of the circuit board 11 such that the longitudinal directions thereof are along the longitudinal direction (left-right) of the circuit board 11. In another embodiment, the fins 220 may have a shape other than a plate-shape, such as a corrugated shape or a pointed shape.

The attachment portion 230 is plate-shaped and thicker than any of the fins 220. The attachment portion 230 is connected to a right-end part of the base 210 such that its longitudinal direction is along the lateral direction (front-rear) of the circuit board 11. In another embodiment, the attachment portion 230 may be connected to a left-end part of the base 210. Alternatively, in another embodiment, the attachment portion 230 may be connected to a front-end part or a rear-end part of the base 210 such that its longitudinal direction is along the longitudinal direction (left-right) of the circuit board 11.

The heat dissipation member 200 includes a first contact surface 200a on the underside of the base 210. The first contact surface 200a is in contact with the first through third semiconductor switches Q1 through Q3 indirectly via the metal plate 100 and so on.

The heat dissipation member 200 includes, on the right end face of the attachment portion 230, a second contact surface 200b distinct from the first contact surface 200a. The second contact surface 200b extends in a direction intersecting the first contact surface 200a. In the present embodiment, the second contact surface 200b extends perpendicularly to the first contact surface 200a.

Referring again to FIGS. 3 and 7, the second contact surface 200b is in contact with the load switch Q7. The load switch Q7 is of a through-hole mounting type. In other words, the load switch Q7 has a through-hole package. More specifically, the load switch Q7 is of a radial lead type. In general, a semiconductor switch having a through-hole package may have a rated voltage and a rated current greater than those of a semiconductor switch having a surface-mount package. In the present embodiment, in order to ensure high reliability and/or high durability, the load switch Q7 has a rated voltage and a rated current higher than those of any of the first through sixth semiconductor switches Q1 through Q6.

The load switch Q7 includes a body 30. The body 30 has a substantially rectangular parallelepiped shape. The load switch Q7 is screwed to the attachment portion 230 with an outer surface of the body 30 in contact with the second contact surface 200b of the attachment portion 230. In another embodiment, the load switch Q7 may be fixed to the attachment portion 230 by being clamped with a clip or the like with the outer surface of the body 30 in contact with the second contact surface 200b. Alternatively, in another embodiment, the outer surface of the body 30 may be adhered to the second contact surface 200b via an interposed member 700, such as a thin adhesive sheet.

Heat generated in the first through third semiconductor switches Q1 through Q3 is conducted to the heat dissipation member 200 via the metal plate 100, and is then dissipated from the heat dissipation member 200. Heat generated in the load switch Q7 is directly conducted to the heat dissipation member 200, and is then dissipated from the heat dissipation member 200.

The load switch Q7 includes a first lead 31, a second lead 32, and a third lead 33. The first lead 31 is coupled to a gate terminal of the load switch Q7. The second lead 32 is coupled to a drain terminal of the load switch Q7. The third lead 33 is coupled to a source terminal of the load switch Q7. The circuit board 11 includes vias 131 through 133 formed thereon. The vias 131 through 133 pass through the circuit board 11 along its thickness. The first through third leads 31 through 33 extend (or protrude) downward from the body 30. The first through third leads 31 through 33 are (i) inserted into the vias 131 through 133 and (ii) electrically coupled to not-shown printed wirings on the first circuit surface 11A through the vias 131 through 133.

Each male screw 400 includes a threaded portion 410. The threaded portion 410 is a helical thread ridge formed on a cylindrical side surface of the male screw 400. The threaded portion 410 is formed in a location, on the male screw 400 inserted through the corresponding insertion hole 250, that corresponds to the corresponding female thread 150. The male screws 400 are each inserted through the corresponding insertion hole 250, and the corresponding threaded portion 410 is threadedly engaged with the corresponding female thread 150. In response to the threaded portions 410 being threadedly engaged with the female threads 150, the heat dissipation member 200 is firmly fixed to the metal plate 100. Moreover, the degree of adhesion between the heat dissipation member 200 and the adhesive layer 300 and between the adhesive layer 300 and the metal plate 100 increases, thus improving the heat dissipation efficiency from the metal plate 100 to the heat dissipation member 200.

In another embodiment, instead of the female threads 150 being formed in the metal plate 100, the drive unit 25 may include two nuts (or female screws) (i.e., the drive unit 25 may include four nuts in total). The two male screws 400 may each be threadedly engaged with a corresponding one of the two nuts at a corresponding location below the right insulating portion 121 or below the left insulating portion 124.

Joined onto the low-side switches are the metal plate 100, and the heat dissipation member 500 in place of the heat dissipation member 200. The heat dissipation member 500 is the same as the heat dissipation member 200 in basic configuration. The heat dissipation member 500 will be described below focusing on the differences from the heat dissipation member 200.

The heat dissipation member 500 includes a base 510, multiple fins 520, and an outer peripheral wall 540. The base 510 is a plate-shaped member greater in length in the longitudinal direction (left-right) of the circuit board 11 than the base 210. The fins 520 have the same shape as the fins 220. The heat dissipation member 500 includes no portion corresponding to the attachment portion 230. The fins 520 are connected to the base 510 such that longitudinal directions thereof are along the lateral direction (front-rear) of the circuit board 11. The fins 520 are arranged in parallel with each other in the longitudinal direction (left-right) of the circuit board 11. In another embodiment, the fins 520 may be arranged in parallel with each other in the lateral direction (front-rear) of the circuit board 11 on the base 510 such that the longitudinal directions thereof are along the longitudinal direction (left-right) of the circuit board 11. In still another embodiment, the fins 520 may have a shape other than a plate-shape, such as a corrugated shape or a pointed shape.

The outer peripheral wall 540 is connected to an upper surface of the base 510. The outer peripheral wall 540 has a height substantially the same as the length from the upper surface of the base 510 to an upper end of the heat dissipation member 200. The outer peripheral wall 540 surrounds the circuit board 11, the two metal plates 100, and the heat dissipation member 200 on the left side, right side, front side, and rear side thereof.

The first through sixth semiconductor switches Q1 through Q6, the two metal plates 100, the heat dissipation members 200 and 500 are assembled to the circuit board 11, and then, resin is injected into the inside of the outer peripheral wall 540, thus molding the drive unit 25 with the resin. The drive unit 25 molded with the resin is housed in the housing 2.

In another embodiment, the outer peripheral wall 540 may be excluded from the heat dissipation member 500. In the case where the outer peripheral wall 540 is excluded, the drive unit 25 is held in a mold and molded with resin. The drive unit 25 molded with the resin is housed in the housing 2. Alternatively, in the case where the outer peripheral wall 540 is excluded, the drive unit 25 may be housed in a casing. The drive unit 25 housed in the casing is housed in the housing 2.

### 1-3-2. Modified Example

A modified example of the drive unit 25 will be described with reference to FIG. 8. The modified example differs from the above-described examples in that the first and second thermistors 27 and 29 each have a third height H3 in place of the second height H2. Moreover, the modified example differs from the above-described examples in that each metal plate 100 does not include the plate through-hole 160. The third height H3 is smaller than the first height H1. Therefore, the first and second thermistors 27 and 29 according to the modified example respectively fit in the space between the first circuit surface 11A and the first insulating portion 122 and the space between the second circuit surface 11B and the first insulating portion 122; thus, the plate through-hole 160 is not provided in each metal plate 100 according to the modified example.

### 1-3-3. Effects

The present embodiment detailed above can achieve the following effects:

(1) The source terminal 43 of the first semiconductor switch Q1 is electrically coupled to the drain terminal 72 of the fourth semiconductor switch Q4 via the metal component 600 inserted into the first board through-hole 501. Since the width of the metal component 600 is larger than a via diameter, the width of each of the first and fourth printed wirings 511 and 521 can be made larger. This in turn makes it possible to reduce the inductance of each of the first and fourth printed wirings 511 and 521. Moreover, since the metal component 600 is solid, the inductance of the metal component 600 can be made lower than that of the via. Accordingly, it is possible to reduce the inductance of the current path on the circuit board 11, thus suppressing the surge voltages generated in association with the switching operations of the first and fourth semiconductor switches Q1 and Q4.

(2) The respective source terminals 43, 53, and 63 of the corresponding first through third semiconductor switches Q1 through Q3 face the respective drain terminals 72, 82, and 92 of the corresponding fourth through sixth semiconductor switches Q4 through Q6, respectively, via the circuit board 11. Thus, the respective printed wirings between the source terminal 43 and the drain terminal 72, between the source terminal 53 and the drain terminal 82, and between the source terminal 63 and the drain terminal 92 can each be shortest. This in turn makes it possible to further reduce the inductance component of the circuit board 11, thus further suppressing the surge voltages generated in association with the switching operations of the first through sixth semiconductor switches Q1 through Q6.

(3) The length of the first part 610 of the metal component 600 in the longitudinal direction thereof is greater than that of each of the first through third board through-holes 501 through 503 in the left-right direction. The length of the second part 620 in the longitudinal direction thereof is smaller than that of each of the first through third board through-holes 501 through 503 in the left-right direction. Accordingly, the second part 620 is accommodated in each of the first through third board through-holes 501 through 503, and part of the lower surface of the first part 610 is in contact with the first circuit surface 11A. This makes it possible to inhibit the metal component 600 from coming off from the circuit board 11.

(4) The first through third board through-holes 501 through 503 extend along the respective second ends 46B, 56B, and 66B of the corresponding first through third semiconductor switches Q1 through Q3, respectively. Thus, the first through third board through-holes 501 through 503 can be arranged in the close vicinity of the first through third semiconductor switches Q1 through Q3, respectively. This in turn makes it possible to further reduce the lengths of the respective printed wirings between the source terminal 43 of the first semiconductor switch Q1 and the drain terminal 72 of the fourth semiconductor switch Q4, between the source terminal 53 of the second semiconductor switch Q2 and the drain terminal 82 of the fifth semiconductor switches Q5, and between the source terminal 63 of the third semiconductor switch Q3 and the drain terminal 92 of the sixth semiconductor switch Q6, thus further suppressing the surge voltages generated in association with the switching operations of the first through sixth semiconductor switches Q1 through Q6.

(5) The solder resist 15 is applied to areas between the second end 46B of the first semiconductor switch Q1 and the first board through-hole 501, between the second end 56B of the second semiconductor switch Q2 and the second board through-hole 502, and between the second end 66B of the third semiconductor switch Q3 and the third board through-hole 503. This makes it possible to avoid contact between the solder joining the metal component 600 to each of the first through third printed wirings 511, 512, and 513 and the solder joining each of the source terminals 43, 53, and 63 to a corresponding one of the first through third printed wirings 511, 512, and 513, respectively.

1-3-4. Correspondence between Terms

In the present embodiment, the metal component 600 corresponds to an example of the solid metal component in Overview of Embodiments, and the first through third board through-holes 501 through 503 each correspond to an example of the through-hole in Overview of Embodiments.

### 2. Other Embodiment

(a) In each of the above-described embodiments, the single metal plate 100 is joined to the three high-side switches, and the other single metal plate 100 is joined to the three low-side switches. However, the present disclosure is not limited thereto. As shown with dotted lines in FIGS. 3, 6, and 7, a single metal plate 100 may be joined to a single semiconductor switch. In such a case where separate metal plates 100 are joined to the corresponding semiconductor switches, the degree of freedom in arranging the semiconductor switches increases. In other words, the three high-side switches and/or the three low-side switches do not necessarily have to be arranged in a row. That is, the six semiconductor switches may be arranged arbitrarily on the first circuit surface 11A and the second circuit surface 11B. Alternatively, a single metal plate 100 may be joined to two of the semiconductor switches. Moreover, a single heat dissipation member 200 or another single heat dissipation member may be fastened to a single metal plate 100 with the male screws 400. Alternatively, a single heat dissipation member 200 or another single heat dissipation member may be fastened to two or more metal plates 100 with the male screws 400.

1. An electric work machine comprising:
a motor configured to receive electric power from a power supply to thereby be driven;
a circuit board including a first circuit surface, a second circuit surface opposite the first circuit surface, and a through-hole;
a first semiconductor switch electrically coupled to the power supply and to the motor and mounted on the first circuit surface, the first semiconductor switch including a first terminal;
a second semiconductor switch electrically coupled to the power supply and to the motor and mounted on the second circuit surface, the second semiconductor switch being distinct from the first semiconductor switch, the second semiconductor switch including a second terminal;
a first conductive trace arranged on the first circuit surface and electrically coupled to the first terminal;
a second conductive trace arranged on the second circuit surface and electrically coupled to the second terminal; and
a solid metal component inserted into the through-hole, the solid metal component being electrically coupled to the first conductive trace and to the second conductive trace.

2. The electric work machine according to claim 1, wherein:
the first semiconductor switch corresponds to a high-side switch of a drive circuit for driving the motor;
the second semiconductor switch corresponds to a low-side switch of the drive circuit; and
the first terminal faces the second terminal via the circuit board.

3. The electric work machine according to claim 1, wherein:
the first semiconductor switch and the second semiconductor switch are each a field-effect transistor;
the first terminal is a source terminal of the first semiconductor switch; and
the second terminal is a drain terminal of the second semiconductor switch.

4. The electric work machine according to claim 1, wherein:
the solid metal component includes: a first part protruding from the through-hole; and a second part accommodated in the through-hole;
the through-hole has a first length in a specified direction along the first circuit surface;
the first part has a second length greater than the first length in the specified direction; and
the second part has a third length smaller than the first length in the specified direction.

5. The electric work machine according to claim 1,
wherein the through-hole extends along an end of the first semiconductor switch.

6. The electric work machine according to claim 5,
wherein the through-hole has a rectangular parallelepiped shape.

7. The electric work machine according to claim 6, wherein:
the first semiconductor switch and the second semiconductor switch each have a rectangular parallelepiped shape;
a transverse direction of the first semiconductor switch is aligned with a transverse direction of the second semiconductor switch; and
a longitudinal direction of the through-hole is aligned with the transverse direction of the first semiconductor switch and the transverse direction of the second semiconductor switch.

8. The electric work machine according to claim 5, further comprising
a solder resist applied to an area, on the first conductive trace, between the end and the through-hole.

9. A method for assembling a drive unit for driving a motor of an electric work machine, the method comprising:
mounting a first semiconductor switch of the drive unit on a first circuit surface of a circuit board of the drive unit, the first circuit surface including a first conductive trace;
mounting a second semiconductor switch of the drive unit distinct from the first semiconductor switch on a second circuit surface opposite the first circuit surface of the circuit board, the second circuit surface including a second conductive trace;
inserting a solid metal component into a through-hole included in the circuit board;
electrically coupling a first terminal of the first semiconductor switch to the first conductive trace;
electrically coupling a second terminal of the second semiconductor switch to the second conductive trace; and
electrically coupling the first conductive trace and the second conductive trace to the solid metal component.

10. The electric work machine according to claim 2, wherein:
the first semiconductor switch and the second semiconductor switch are each a field-effect transistor;
the first terminal is a source terminal of the first semiconductor switch; and
the second terminal is a drain terminal of the second semiconductor switch.

11. The electric work machine according to claim 2, wherein:
the solid metal component includes: a first part protruding from the through-hole; and a second part accommodated in the through-hole;
the through-hole has a first length in a specified direction along the first circuit surface;
the first part has a second length greater than the first length in the specified direction; and
the second part has a third length smaller than the first length in the specified direction.

12. The electric work machine according to claim 3, wherein:
the solid metal component includes: a first part protruding from the through-hole; and a second part accommodated in the through-hole;
the through-hole has a first length in a specified direction along the first circuit surface;
the first part has a second length greater than the first length in the specified direction; and
the second part has a third length smaller than the first length in the specified direction.

13. The electric work machine according to claim 2,
wherein the through-hole extends along an end of the first semiconductor switch.

14. The electric work machine according to claim 3,
wherein the through-hole extends along an end of the first semiconductor switch.

15. The electric work machine according to claim 4,
wherein the through-hole extends along an end of the first semiconductor switch.
